(19) United States
(12) Patent Application Publication
(10) Pub. No.: US 2024/0380377 A1
(43) Pub. Date: Nov. 14, 2024

(54) ACOUSTIC WAVE DEVICE

(71) Applicant: Murata Manufacturing Co., Ltd., Nagaokakyo-shi (JP)

(72) Inventor: Hideki IWAMOTO, Nagaokakyo-shi (JP)

(21) Appl. No.: 18/591,099

(22) Filed: Feb. 29, 2024

(30) Foreign Application Priority Data
May 11, 2023 (JP) 2023-078365

(51) Int. Cl. H03H 9/02; H03H 3/02

(52) U.S. Cl. CPC H03H 9/02574; H03H 9/02559; H03H 3/02

(57) ABSTRACT

An acoustic wave device includes a support substrate, a piezoelectric layer directly on or indirectly above the support substrate, and an IDT electrode on the piezoelectric layer. The piezoelectric layer includes at least one rotated Y-cut lithium tantalate layer and at least one rotated Y-cut lithium niobate layer alternately laminated. A total number of the lithium tantalate layers and the lithium niobate layers is three or more.

### CROSS REFERENCE TO RELATED APPLICATIONS

This application claims the benefit of priority to Japanese Patent Application No. 2023-078365 filed on May 11, 2023. The entire contents of this application are hereby incorporated herein by reference.

### BACKGROUND OF THE INVENTION

### 1. Field of the Invention

The present invention relates to acoustic wave devices.

### 2. Description of the Related Art

Conventionally, acoustic wave devices have been broadly used for filters of cellular phones and the like. An example of an acoustic wave device is disclosed in International Publication No. 2021/177341. In the acoustic wave device, a multilayer body is provided on a support substrate. Interdigital transducer (IDT) electrodes are provided on the multilayer body. The multilayer body includes one lithium tantalate piezoelectric layer and one lithium niobate piezoelectric layer.

When using an acoustic wave device as a filter device, an optimum fractional bandwidth in the acoustic wave device differs depending on a communication band for the filter device. In the acoustic wave device according to International Publication No. 2021/177341, however, it is difficult to sufficiently broaden the fractional bandwidth. Accordingly, it may be difficult to adjust the fractional bandwidth of the acoustic wave device to a value suitable for the filter device.

### SUMMARY OF THE INVENTION

Example embodiments of the present invention provide acoustic wave devices each structured such that a fractional bandwidth is able to be easily adjusted.

An acoustic wave device according to an example embodiment of the present invention includes a support substrate, a piezoelectric layer directly on or indirectly above the support substrate, and an IDT electrode on the piezoelectric layer. The piezoelectric layer includes at least one rotated Y-cut lithium tantalate layer and at least one rotated Y-cut lithium niobate layer alternately laminated. A total number of the at least one lithium tantalate layer and the at least one lithium niobate layers is three or more.

According to example embodiments of the present invention, acoustic wave devices in each of which the fractional bandwidth is able to be easily adjusted are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view illustrating a portion of an acoustic wave device according to a first example embodiment of the present invention.

FIG. 2 is a schematic elevational cross-sectional view illustrating a portion of FIG. 1 with enlargement.

FIG. 3 is a schematic plan view of the acoustic wave device according to the first example embodiment of the present invention.

FIG. 4 is a diagram illustrating impedance frequency characteristics in the first example embodiment of the present invention, a first comparative example, and a second comparative example.

FIG. 5 is a diagram illustrating a relationship between numbers of lithium tantalate layers and lithium niobate layers and fractional bandwidths.

FIG. 6 is a diagram illustrating impedance frequency characteristics in a third comparative example.

FIG. 7 is a diagram illustrating impedance frequency characteristics in a vicinity of a frequency at which Rayleigh mode occurs in the first example embodiment of the present invention.

FIG. 8 is a schematic elevational cross-sectional view illustrating, with enlargement, a portion of a piezoelectric layer in a second example embodiment of the present invention.

FIG. 9 is a diagram illustrating impedance frequency characteristics in a vicinity of a frequency at which Rayleigh mode occurs in the first example embodiment and the second example embodiment of the present invention.

FIG. 10 is a schematic elevational cross-sectional view illustrating a vicinity of a pair of electrode fingers in an acoustic wave device according to a first modification of the second example embodiment of the present invention.

FIG. 11 is a schematic elevational cross-sectional view illustrating a vicinity of a pair of electrode fingers in an acoustic wave device according to a second modification of the second example embodiment of the present invention.

### DETAILED DESCRIPTION OF THE EXAMPLE EMBODIMENTS

Hereinbelow, the present invention will be clarified by description of example embodiments of the present invention with reference to the drawings.

The example embodiments disclosed herein are exemplary and partial substitution or combination of configurations can be made among different example embodiments.

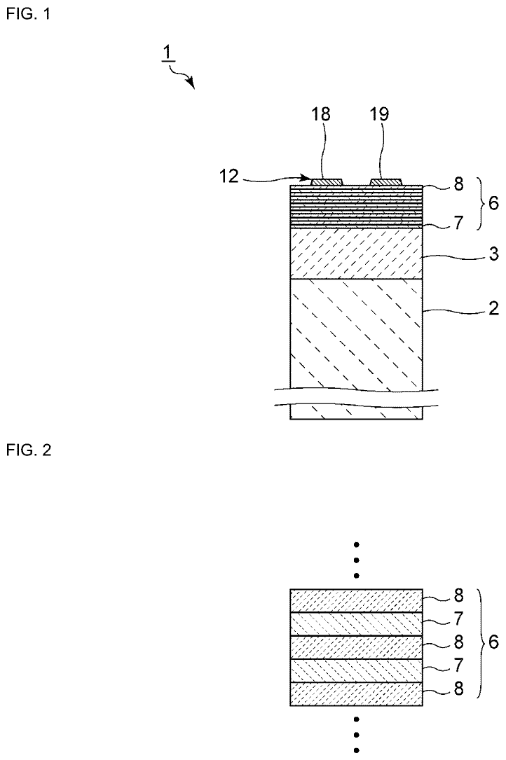

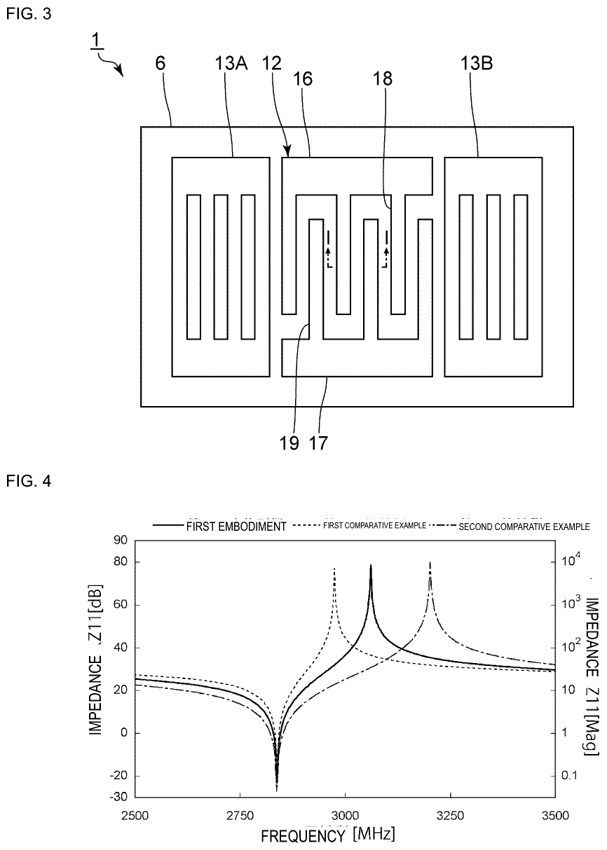

FIG. 1 is a schematic elevational cross-sectional view illustrating a portion of an acoustic wave device according to a first example embodiment of the present invention. FIG. 2 is a schematic elevational cross-sectional view illustrating a portion of FIG. 1 with enlargement. FIG. 3 is a schematic plan view of the acoustic wave device according to the first example embodiment. Incidentally, FIG. 1 is the schematic cross-sectional view taken along line I-I in FIG. 3.

As illustrated in FIG. 1, an acoustic wave device 1 includes a support substrate 2, an interlayer 3, and a piezoelectric layer 6. The interlayer 3 is provided on the support substrate 2. The piezoelectric layer 6 is provided on the interlayer 3. The piezoelectric layer 6 is a layer in which material having piezoelectricity is used. Thus, the piezoelectric layer 6 has piezoelectricity.

As illustrated in FIGS. 1 and 2, the piezoelectric layer 6 is a multilayer body including a plurality of piezoelectric layers. Specifically, the plurality of piezoelectric layers include a plurality of lithium tantalate layers 7 and a plurality of lithium niobate layers 8. In the piezoelectric layer 6, the lithium tantalate layers 7 and the lithium niobate layers 8 are alternately laminated.

More specifically, each of the plurality of lithium tantalate layers 7 example, a rotated Y-cut lithium tantalate layer. In the present example embodiment, each of the lithium tantalate layers 7 is, for example, a LiTaO₃ layer. Further, a cut-angle of each of the lithium tantalate layers 7 is, for example, about 35° Y and Euler angles thereof are (0°, 125°) 0°. The cut-angle of the lithium tantalate layers 7, however, is not limited to the above.

On the other hand, each of the plurality of lithium niobate layers 8 is, for example, a rotated Y-cut lithium niobate layer. In the present example embodiment, each of the lithium niobate layers 8 is, for example, a LiNbO₃ layer. Further, a cut-angle of each of the lithium niobate layers 8 is, for example, about 45° Y and Euler angles thereof are (0°, 135°) 0°. The cut-angle of the lithium niobate layers 8, however, is not limited to the above.

It is sufficient if the piezoelectric layer 6 includes three or more piezoelectric layers. It is sufficient if the plurality of piezoelectric layers include at least one rotated Y-cut lithium tantalate layer 7 and at least one rotated Y-cut lithium niobate layer 8. When the number of plurality of piezoelectric layers is three, the number of rotated Y-cut lithium tantalate layers 7 may be two or the number of rotated Y-cut lithium niobate layers 8 may be two.

In the present example embodiment, as illustrated in FIG. 1, the piezoelectric layer 6 is indirectly provided above the support substrate 2 with the interlayer 3 interposed therebetween. The interlayer 3 does not have to be provided. The piezoelectric layer 6 may be directly provided on the support substrate 2.

The interlayer 3 is a single dielectric layer. Silicon oxide, for example, is used as a material of the interlayer 3. Thus, an absolute value of a temperature coefficient of frequency (TCF) of the acoustic wave device 1 can be made small and frequency-temperature characteristics of the acoustic wave device 1 can be improved. The material of the interlayer 3, however, is not limited to the above. For example, silicon nitride, polysilicon, or the like may be used as the material of the interlayer 3.

Specifically, the support substrate 2 is, for example, a silicon substrate. A plane direction of the support substrate 2 is (111). More specifically, the plane direction of a surface of the support substrate 2 on a side of the piezoelectric layer 6 is (111). In the present example embodiment, Euler angles of the support substrate 2 are, for example, (−45°, −54.7°, 73°. The Euler angles and the plane direction of the support substrate 2, however, are not limited to the above. Further, a material of the support substrate 2 is not limited to silicon. For example, ceramic such as aluminum oxide or the like may be used as the material of the support substrate 2, for instance.

An IDT electrode 12 is provided on the piezoelectric layer 6. As illustrated in FIG. 3, the IDT electrode 12 includes a pair of busbars and a plurality of electrode fingers. Specifically, the pair of busbars include a first busbar 16 and a second busbar 17. The first busbar 16 and the second busbar 17 are opposed to each other. The plurality of electrode fingers include a plurality of first electrode fingers 18 and a plurality of second electrode fingers 19. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The first electrode fingers 18 and the second electrode fingers 19 are connected to different potentials.

Acoustic waves are excited by application of alternating-current voltages to the IDT electrode 12. A direction in which the plurality of first electrode fingers 18 and the plurality of second electrode fingers 19 extend is orthogonal or substantially orthogonal to a propagation direction of the acoustic waves. A pair of a reflector 13A and a reflector 13B are provided on the piezoelectric layer 6. More specifically, the reflector 13A and the reflector 13B are provided so as to be opposed to each other with the IDT electrode 12 interposed therebetween in the propagation direction of the acoustic waves. The acoustic wave device 1 is, for example, a surface acoustic wave resonator. In the present example embodiment, an SH mode is excited as a main mode. In this case, Rayleigh mode becomes unwanted waves.

In the present example embodiment, the IDT electrode 12 and the reflectors include laminated metal films. More specifically, a layer configuration of the IDT electrode 12 and the reflectors includes a Ti layer, an AlCu layer, and a Ti layer that are laminated in this order from a side of the piezoelectric layer 6. Materials of the IDT electrode 12 and the reflectors, however, are not limited to the above. Alternatively, for example, the IDT electrode 12 and the reflectors may include a single layer of a metal film.

Hereinbelow, a wavelength defined by an electrode finger pitch of the IDT electrode 12 will be represented as A. The electrode finger pitch refers to a center-to-center distance between a first electrode finger 18 and a second electrode finger 19 that adjoin, in the propagation direction of the acoustic waves. Providing that the electrode finger pitch is represented as p, for instance, λ=2p is satisfied.

As illustrated in FIG. 1, the piezoelectric layer that is positioned so as to be the nearest to the IDT electrode 12 in the piezoelectric layer 6 is, for example, the lithium niobate layer 8. The piezoelectric layer that is positioned so as to be the nearest to the IDT electrode 12 may be, for example, the lithium tantalate layer 7. On the other hand, the piezoelectric layer that is positioned so as to be the nearest to the support substrate 2 is, for example, the lithium tantalate layer 7. The piezoelectric layer that is positioned so as to be the nearest to the support substrate 2 may be, for example, the lithium niobate layer 8.

Characteristics of the present example embodiment are inclusion of following configurations. 1) The rotated Y-cut lithium tantalate layers 7 and the rotated Y-cut lithium niobate layers 8 are alternately laminated in the piezoelectric layer 6. 2) The total number of the rotated Y-cut lithium tantalate layers 7 and the rotated Y-cut lithium niobate layers 8 is three or more. Thus, a fractional bandwidth can be easily adjusted. Providing that a resonant frequency is fr and that an anti-resonant frequency is fa, the fractional bandwidth is represented by (|fa-fr|/fr)×100 [%]. Details of the above-described advantageous effects will be described below.

Impedance frequency characteristics were compared between the acoustic wave device 1 having the configuration of the first example embodiment and acoustic wave devices of a first comparative example and a second comparative example. The first comparative example differs from the first example embodiment in that a piezoelectric layer includes a single rotated Y-cut lithium tantalate layer. The second comparative example differs from the first example embodiment in that a piezoelectric layer includes a single rotated Y-cut lithium niobate layer. The impedance frequency characteristics of the acoustic wave devices of the first example embodiment, the first comparative example, and the second comparative example were derived based on simulations. Design parameters of the acoustic wave device 1 having the configuration of the first example embodiment are as follows.

Support substrate: material. Si, plane direction. (111), Euler angles . . . (−45°, −54.7°, 73°)

Interlayer: material . . . SiO₂, thickness . . . about 300 nm

Piezoelectric material layer: total number of lithium tantalate layers and lithium niobate layers . . . 20 layers, total thickness of lithium tantalate layers and lithium niobate layers . . . about 400 nm

Lithium tantalate layers: material . . . LiTaO₃ of rotated Y-cut X SAW propagation, cut-angle . . . about 35° Y, Euler angles . . . (0°, 125°) 0°, thickness . . . about 20 nm, number of layers . . . 10 layers

Lithium niobate layers: material . . . LiNbO₃ of rotated Y-cut X SAW propagation, cut-angle . . . about 45° Y, Euler angles . . . (0°, 135°) 0°, thickness . . . about 20 nm, number of layers . . . 10 layers

IDT electrode: layer configuration . . . Ti layer/AlCu layer/Ti layer from side of piezoelectric layer, thickness . . . about 12 nm/about 10 nm/about 4 nm

Wavelength about 1.346 μm

Duty ratio . . . about 0.45

A cut-angle of the lithium tantalate layers of the first comparative example is about 35° Y. A cut-angle of the lithium niobate layers of the second comparative example is about 45° Y.

FIG. 4 is a diagram illustrating the impedance frequency characteristics in the first example embodiment, the first comparative example, and the second comparative example. In FIG. 4, resonant frequencies in the first example embodiment, the first comparative example, and the second comparative example are expressed so as to the same or substantially the same. In the first example embodiment, the first comparative example, and the second comparative example, accordingly, the higher the anti-resonant frequency is, the greater the fractional bandwidth is.

As illustrated in FIG. 4, a value of the fractional bandwidth in the first example embodiment is intermediate between values of the fractional bandwidths in the first comparative example and the second comparative example. Specifically, the fractional bandwidth in the first example embodiment is about 7.8%. The fractional bandwidth in the first comparative example is about 4.8%. The fractional bandwidth in the second comparative example is about 12.8%.

When an acoustic wave device is used as an acoustic wave resonator for a high-frequency filter, optimum fractional bandwidths in the acoustic wave device differ depending on a communication band of the filter device. For instance, the optimum fractional bandwidth in the acoustic wave device may be about 8%. In a conventional acoustic wave device such as the first comparative example or the second comparative example, it has been difficult to make the fractional bandwidth in the acoustic wave device close to an optimum value. In the first example embodiment, by contrast, adjustment of the fractional bandwidth that has been difficult to make in the conventional acoustic wave devices can be made easily.

Further, the fractional bandwidth was calculated based on a simulation each time the number of the lithium tantalate layers and the lithium niobate layers in the piezoelectric layer was varied. More specifically, the fractional bandwidth when the piezoelectric layer which was positioned so as to be the nearest to the IDT electrode was the lithium tantalate layer was calculated. The fractional bandwidth when the piezoelectric layer which was positioned so as to be the nearest to the IDT electrode was the lithium niobate layer was calculated as well.

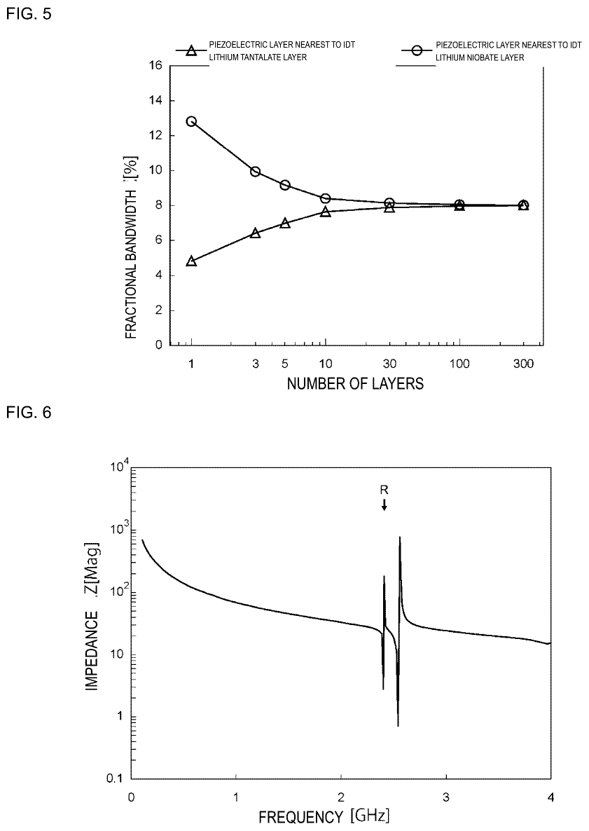

FIG. 5 is a diagram illustrating a relationship between numbers of lithium tantalate layers and lithium niobate layers and fractional bandwidths. A horizontal axis in FIG. 5 represents the total number of the lithium tantalate layers and the lithium niobate layers. A plot of triangles represents results when the piezoelectric layer positioned so as to be the nearest to the IDT electrode is the lithium tantalate layer. Accordingly, the result of the plot of the triangle with a value on the horizontal axis being 1 corresponds to a result of the first comparative example. A plot of circles represents results when the piezoelectric layer positioned so as to be the nearest to the IDT electrode is the lithium niobate layer. Accordingly, the result of the plot of the circle with a value on the horizontal axis being 1 corresponds to a result of the second comparative example.

As illustrated in FIG. 5, it was discovered that a difference in the numbers of the lithium tantalate layers and the lithium niobate layers results in a difference in the fractional bandwidth. More specifically, the greater the number of the lithium tantalate layers is, the greater the value of the fractional bandwidth is. On the other hand, the greater the number of the lithium niobate layers is, the smaller the value of the fractional bandwidth is.

Based on these results, it was discovered that the fractional bandwidth can be adjusted by adjustment of the numbers of the lithium tantalate layers 7 and the lithium niobate layers 8 which are illustrated in FIG. 1. Further, the total number of the lithium tantalate layers 7 and the lithium niobate layers 8 is, for example, three or more as in the first example embodiment, so that the fractional bandwidth can be easily adjusted over a wide range.

The total number of the lithium tantalate layers 7 and the lithium niobate layers 8 in the piezoelectric layer 6 is preferably, for example, ten or more, and more preferably thirty or more. Thus, a variation in the fractional bandwidth of the acoustic wave device 1 can be reduced or prevented. On the other hand, the total number of the lithium tantalate layers 7 and the lithium niobate layers 8 in the piezoelectric layer 6 is preferably, for example, 100 or less. In this configuration, the fractional bandwidth of the acoustic wave device 1 can be favorably adjusted and a decrease in productivity can be reduced or prevented.

In the first example embodiment, use of the rotated Y-cut lithium tantalate layers 7 and the rotated Y-cut lithium niobate layers 8 facilitates the adjustment of the fractional bandwidth. Further, a Rayleigh mode as unwanted waves can be reduced or prevented as well. The above will be described with reference to a third comparative example.

The third comparative example differs from the first example embodiment in that both the lithium tantalate layers and the lithium niobate layers have (001) orientation. In the third comparative example, the lithium tantalate layers and the lithium niobate layers are alternately laminated. Additionally, the total number of the lithium tantalate layers and the lithium niobate layers is, for example, 20.

FIG. 6 is a diagram illustrating impedance frequency characteristics in the third comparative example.

In the third comparative example, as illustrated in FIG. 6, a value of the fractional bandwidth is extremely small. Specifically, the fractional bandwidth in the third comparative example is for example, about 0.8%. When being used for a filter device, therefore, it may be impossible to favorably configure a pass band. As illustrated by an arrow R in FIG. 6, large unwanted waves are generated. The unwanted waves are of Rayleigh mode.

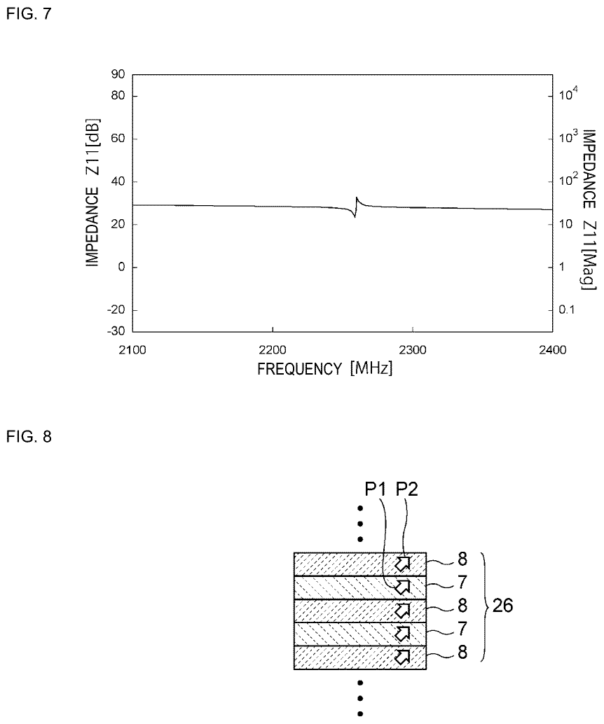

FIG. 7 is a diagram illustrating impedance frequency characteristics in a vicinity of a frequency at which Rayleigh mode occurs in the first example embodiment.

As illustrated in FIG. 7, it was discovered that Rayleigh waves as the unwanted waves are further reduced or prevented in the first example embodiment, compared with the third comparative example illustrated in FIG. 6. In the first example embodiment as illustrated in FIG. 5, the fractional bandwidth can be easily adjusted within a range of, for example, about 4%. These are because the rotated Y-cut lithium tantalate layers 7 and the rotated Y-cut lithium niobate layers 8 are used in the first example embodiment, as described above.

The results illustrated in FIG. 5 are results when the lithium tantalate layers 7 and the lithium niobate layers 8 have equal or substantially equal thicknesses. In the present invention, however, the lithium tantalate layers 7 and the lithium niobate layers 8 may have different thicknesses. Otherwise, the lithium tantalate layers 7 may have different thicknesses. The lithium niobate layers 8 may have different thicknesses. That is, the fractional bandwidth can be adjusted by adjustment of the number and the thicknesses of the lithium tantalate layers 7 and the number and the thicknesses of the lithium niobate layers 8.

Hereinbelow, a second example embodiment of the present invention that differs from the first example embodiment in a configuration of the piezoelectric layer will be described. In the second example embodiment, however, configurations of others than the piezoelectric layer are the same as or similar to the configurations of the first example embodiment. Therefore, the drawings and the reference characters that have been used to describe the first example embodiment may be referred to in the description of the second example embodiment.

FIG. 8 is a schematic elevational cross-sectional view illustrating, with enlargement, a portion of a piezoelectric layer in the second example embodiment.

The present example embodiment differs from the first example embodiment in that the lithium tantalate layers 7 and the lithium niobate layers 8 have the same or substantially the same cut-angle. Other than the above, an acoustic wave device of the present example embodiment has configurations the same as or similar to the configurations of the acoustic wave device 1 of the first example embodiment.

In FIG. 8, a direction of polarization of the lithium tantalate layers 7 is illustrated by arrows P1. A direction of polarization of the lithium niobate layers 8 is illustrated by arrows P2. The direction of polarization of the lithium tantalate layers 7 is the same or substantially the same as the direction of polarization of the lithium niobate layers 8.

In the present example embodiment as well, the rotated Y-cut lithium tantalate layers 7 and the rotated Y-cut lithium niobate layers 8 are alternately laminated in a piezoelectric layer 26, as with the first example embodiment. Further, the total number of the rotated Y-cut lithium tantalate layers 7 and the rotated Y-cut lithium niobate layers 8 is, for example, three or more. Thus, the fractional bandwidth of the acoustic wave device can be easily adjusted.

In the present example embodiment, additionally, a Rayleigh mode as the unwanted waves can be further reduced or prevented. This will be described below.

As an acoustic wave device having the configuration of the second example embodiment, an acoustic wave device in which the lithium tantalate layers 7 and the lithium niobate layers 8 had the cut-angle of about 45° Y was prepared. As another acoustic wave device having the configuration of the second example embodiment, an acoustic wave device in which the lithium tantalate layers 7 and the lithium niobate layers 8 had the cut-angle of about 35° Y was prepared. Design parameters of those acoustic wave devices are the same as or similar to the design parameters of the acoustic wave device 1 of the first example embodiment having the impedance frequency characteristics illustrated in FIG. 4, except for the cut-angle of the lithium tantalate layers 7 and the lithium niobate layers 8.

Impedance frequency characteristics of the acoustic wave devices having the configuration of the second example embodiment were derived based on simulations. The result of the first example embodiment will be additionally described.

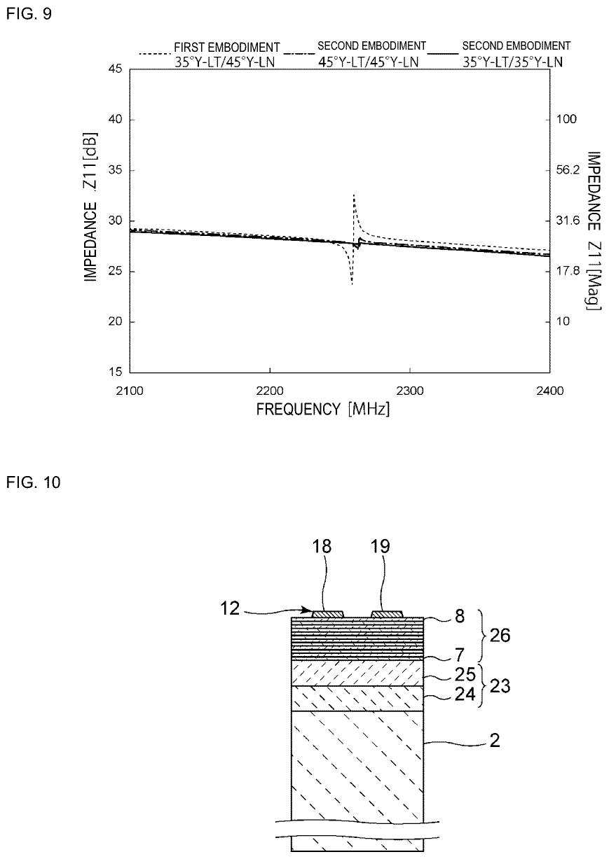

FIG. 9 is a diagram illustrating impedance frequency characteristics in a vicinity of a frequency at which a Rayleigh mode occurs in the first example embodiment and the second example embodiment. In FIG. 9, the lithium tantalate layers are represented as LT and the lithium niobate layers are represented as LN.

In the first example embodiment, as illustrated in FIG. 9, a Rayleigh mode as the unwanted waves is sufficiently reduced or prevented. In the second example embodiment, meanwhile, a Rayleigh mode is further reduced or prevented. More specifically, a Rayleigh mode is further reduced or prevented on both of a condition that the cut-angle of the lithium tantalate layers 7 and the lithium niobate layers 8 is about 35° Y and a condition that the cut-angle is about 45° Y.

It is preferable that an absolute value of a difference in the cut-angle between a lithium tantalate layer 7 and a lithium niobate layer 8 that adjoin in a direction of thickness of the piezoelectric layer 6 is for example, about 0.5° or less. In this configuration, in the present invention, it can be said that the lithium tantalate layer 7 and the lithium niobate layer 8 that adjoin are substantially equal in the cut-angle. Therefore, a Rayleigh mode as the unwanted waves can be further reduced or prevented, providing that the absolute value of the difference in the cut-angle between both the layers is about 0.5° or less. It is more preferable that an absolute value of a difference between a greatest value and a smallest value of the cut-angles of the lithium tantalate layers 7 and the lithium niobate layers 8 in the piezoelectric layer 26 is, for example, about 0.5° or less. In this configuration, a Rayleigh mode as the unwanted waves can be reduced or prevented more reliably.

In the second example embodiment, additionally, frequency-temperature characteristics of the acoustic wave device can be improved effectively. In the first example embodiment as well, the frequency-temperature characteristics of the acoustic wave device 1 can be improved. This will be described below in comparison with the first comparative example, the second comparative example, and a fourth comparative example.

In the first comparative example, as described above, the piezoelectric layer is a single lithium tantalate layer. In the second comparative example, the piezoelectric layer is a single lithium niobate layer. In the fourth comparative example, meanwhile, the piezoelectric layer is a multilayer body including one lithium tantalate layer and one lithium niobate layer.

Herein, TCF in the resonant frequency of an acoustic wave device is represented as TCFr [ppm/° C.], TCF in the anti-resonant frequency is represented as TCFa [ppm/° C.], and a difference between TCFr and TCFa is represented as ΔTCF [ppm/C]. Specifically, ΔTCF=TCFa-TCFr holds. In Table 1, ΔTCF in the first example embodiment, the second example embodiment, the first comparative example, the second comparative example, and the fourth comparative example is listed. In Table 1, the lithium tantalate layers are represented as LT and the lithium niobate layers are represented as LN.

TABLE 1

| | | Lamination | ATCF |
|---|---|---|---|
| | Structure | structure | [ppm/° C.] |
| First | 35° Y-LT | Single layer | 15 |
| comparative | | | |
| example | | | |
| Second | 35° Y-LN | Single layer | −22 |
| comparative | | | |
| example | | | |
| Fourth | 35° Y-LT/ | Two layers | −15 |
| comparative | 35° Y-LN | | |
| example | | | |
| First example | 35° Y-LT/ | Multilayer | 9 |
| embodiment | 45° Y-LN | | |
| Second example | 35° Y-LT/ | Multilayer | 6 |
| embodiment | 35° Y-LN | | |

As shown in Table 1, it was discovered that the first example embodiment is smaller in absolute value of ΔTCF than the comparative examples. In the first example embodiment, specifically, ΔTCF is about 9 ppm/° C. and can be maintained at a single-digit level. This is because the piezoelectric layer 6 illustrated in FIG. 1 includes the multilayer body made of the lithium tantalate layers 7 and the lithium niobate layers 8 and has a multilayer structure. It was discovered that the absolute value of ΔTCF is still smaller in the second example embodiment. This is because the lithium tantalate layers 7 and the lithium niobate layers 8 that adjoin in a direction of thickness of the piezoelectric layer 26 are uniform or substantially uniform in direction as illustrated in FIG. 8.

When absolute value of the difference in the cut-angle between the lithium tantalate layers 7 and the lithium niobate layers 8 that adjoin in the direction of thickness of the piezoelectric layer 6 is about 0.5° or less as well, the absolute value of ΔTCF can be made still smaller as with the second example embodiment. The absolute value of ΔTCF can be made still smaller when the absolute value of the difference between the greatest value and the smallest value of the cut-angles of the lithium tantalate layers 7 and the lithium niobate layers 8 in the piezoelectric layer 26 is about 0.5° or less, as well.

In the second example embodiment, meanwhile, the interlayer 3 is a single dielectric layer as illustrated with citation of FIG. 1. In the present invention, however, the interlayer 3 may be a multilayer body. In a first modification of the second example embodiment illustrated in FIG. 10, for instance, an interlayer 23 includes a high acoustic velocity film 24 and a low acoustic velocity film 25. Specifically, the high acoustic velocity film 24 is provided on the support substrate 2. The low acoustic velocity film 25 is provided on the high acoustic velocity film 24. The piezoelectric layer 26 is provided on the low acoustic velocity film 25.

The high acoustic velocity film 24 is a relatively high acoustic velocity film. More specifically, an acoustic velocity of bulk waves propagating in the high acoustic velocity film 24 is higher than acoustic velocities of acoustic waves propagating in piezoelectric layers in the piezoelectric layer 26. As material of the high acoustic velocity film 24, piezoelectric material such as, for example, aluminum nitride, lithium tantalate, lithium niobate, or crystal, ceramic such as alumina, sapphire, magnesia, silicon nitride, silicon carbide, zirconia, cordierite, mullite, steatite, forsterite, spinel, or sialon, dielectric such as aluminum oxide, silicon oxynitride, diamond-like carbon (DLC), or diamond, semiconductor such as silicon, or material including the above material as a major ingredient may be used, for instance. Aluminum compounds including, for example, one or more elements selected from Mg, Fe, Zn, Mn and the like and oxygen are included in the spinel. MgAl₂O₄, FeAl₂O₄, ZnAl₂O₄, and MnAl₂O₄ can be cited as examples of the spinel.

Herein, “major ingredient” refers to an ingredient of which a content rate exceeds 50% by weight. The material as the above major ingredient may exist in a state of any of single crystal, polycrystal, and amorphous or a state of mixture thereof.

The low acoustic velocity film 25 is a relatively low acoustic velocity film. More specifically, an acoustic velocity of bulk waves propagating in the low acoustic velocity film 25 is lower than acoustic velocities of bulk waves propagating in piezoelectric layers in the piezoelectric layer 26. As material of the low acoustic velocity film 25, dielectric such as, for example, glass, silicon oxide, silicon oxynitride, lithium oxide, tantalum oxide, or a compound including fluorine, carbon, boron added to silicon oxide, or material including above material as a major ingredient may be used.

The high acoustic velocity film 24, the low acoustic velocity film 25, and the piezoelectric layer 26 are laminated in this order in the acoustic wave device, such that energy of acoustic waves can be effectively confined on a side of the piezoelectric layer 26. In the present modification as well, additionally, the fractional bandwidth of the acoustic wave device can be easily adjusted, as with the second example embodiment.

In the second example embodiment for example, silicon is used as the material of the support substrate 2. In the present invention, however, the materials cited as examples of the material of the high acoustic velocity film 24 may be used as the material of the support substrate 2.

When the interlayer 23 is a multilayer body, the interlayer 23 does not have to include the high acoustic velocity film 24 and the low acoustic velocity film 25. The interlayer 23, however, preferably includes for example, a layer in which silicon oxide is used as the material. Thus, the frequency-temperature characteristics of the acoustic wave device can be improved.

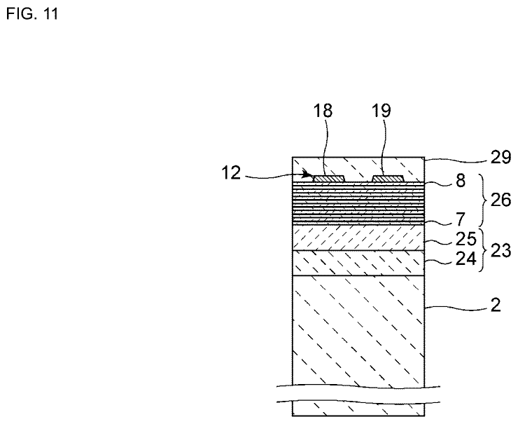

On the piezoelectric layer 26, meanwhile, a dielectric film may be provided. In a second modification of the second example embodiment illustrated in FIG. 11, for example, a dielectric film 29 is provided on the piezoelectric layer 26 so as to cover the IDT electrode 12. Thus, the IDT electrode 12 is protected by the dielectric film 29 and the IDT electrode 12 therefore resists being damaged. In the present modification as well, additionally, the fractional bandwidth of the acoustic wave device can be easily adjusted, as with the second example embodiment. For example, silicon oxide, silicon nitride, silicon oxynitride, or the like may be used as material of the dielectric film 29.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a piezoelectric layer directly on or indirectly above the support substrate; and
an interdigital transducer (IDT) electrode on the piezoelectric layer; wherein
the piezoelectric layer includes at least one rotated Y-cut lithium tantalate layer and at least one rotated Y-cut lithium niobate layer alternately laminated, and a total number of the at least one rotated Y-cut lithium tantalate layer and the at least one rotated Y-cut lithium niobate layer is three or more.

2. The acoustic wave device according to claim 1, wherein an absolute value of a difference in cut-angle between the at least one rotated Y-cut lithium tantalate layer and the at least one rotated Y-cut lithium niobate layer in a direction of thickness of the piezoelectric layer is about 0.5° or less.

3. The acoustic wave device according to claim 1, wherein a total number of the at least one rotated Y-cut lithium tantalate layer and the at least one rotated Y-cut lithium niobate layer in the piezoelectric layer is 10 or more and 100 or less.

4. The acoustic wave device according to claim 3, wherein the total number of the at least one rotated Y-cut lithium tantalate layer and the at least one rotated Y-cut lithium niobate layer in the piezoelectric layer is 30 or more and 100 or less.

5. The acoustic wave device according to claim 1, further comprising an interlayer between the support substrate and the piezoelectric layer and including a layer including silicon oxide.

6. The acoustic wave device according to claim 1, wherein the support substrate includes silicon.

7. The acoustic wave device according to claim 1, further comprising a dielectric film provided on the piezoelectric layer and covering the IDT electrode.

8. The acoustic wave device according to claim 1, wherein a cut angle of the lithium tantalate layers is about 35° Y.

9. The acoustic wave device according to claim 1, wherein a cut angle of the at least one rotated Y-cut lithium niobate layer is about 45° Y.

10. The acoustic wave device according to claim 1, wherein the support substrate includes aluminum oxide.

11. The acoustic wave device according to claim 1, wherein the IDT electrode includes a plurality of laminated metal films.

12. The acoustic wave device according to claim 1, wherein the IDT electrode includes a Ti layer, an AlCu layer, and a Ti layer laminated in this order from a side of the piezoelectric layer.

13. The acoustic wave device according to claim 1, wherein the IDT electrode includes a single layer of metal.

14. The acoustic wave device according to claim 1, further comprising an interlayer between the support substrate and the piezoelectric layer.

15. The acoustic wave device according to claim 14, wherein the interlayer includes a high acoustic velocity film on the support substrate and a low acoustic velocity film on the high acoustic velocity film.

16. The acoustic wave device according to claim 15, wherein the high acoustic velocity film includes aluminum nitride, lithium tantalate, lithium niobate, or crystal alumina.

17. The acoustic wave device according to claim 15, wherein the high acoustic velocity film includes sapphire, magnesia, silicon nitride, silicon carbide, zirconia, cordierite, mullite, steatite, forsterite, spinel, or sialon.

18. The acoustic wave device according to claim 15, wherein the low acoustic velocity film includes glass, silicon oxide, silicon oxynitride, lithium oxide, tantalum oxide, or a compound including fluorine, carbon, boron added to silicon oxide.
